(19) United States
(12) Patent Application Publication
(10) Pub. No.: US 2019/0358859 A1
(43) Pub. Date: Nov. 28, 2019

(54) SEMICONDUCTOR DEVICE AND METHOD FOR MANUFACTURING SAME

(71) Applicant: DENSO CORPORATION, Kariya-city (JP)

(72) Inventors: Ryosuke IZUMI, Kariya-city (JP); Norihito YOSHIDA, Kariya-city (JP)

(21) Appl. No.: 16/526,227

(22) Filed: Jul. 30, 2019

Related U.S. Application Data
(63) Continuation of application No. PCT/JP2018/005509, filed on Feb. 16, 2018.

(30) Foreign Application Priority Data
Feb. 28, 2017 (JP) 2017-037277

(51) Int. Cl. B29C 33/12; B29C 45/14; H01L 21/56; H01L 23/31

(52) U.S. Cl. CPC B29C 33/12; H01L 23/31; H01L 21/56; B29C 45/14065

(57) ABSTRACT

A semiconductor device includes: a primary molded body includes a semiconductor chip that has a detector for detecting a physical quantity, and a primary molded resin having a resin material; a housing component includes an insertion hole for inserting the primary molded body; and a secondary molded resin, which is made of a resin material, that integrally covers a region exposed from the insertion hole, the region being a part of a surface of the primary molded body, and a part of a region of a surface of the housing component including a region surrounding the insertion hole. A part of the primary molded body including the semiconductor chip is in the insertion hole.

### CROSS REFERENCE TO RELATED APPLICATION

The present application is a continuation application of International Patent Application No. PCT/JP2018/005509 filed on Feb. 16, 2018, which designated the U.S. and claims the benefit of priority from Japanese Patent Application No. 2017-037277 filed on Feb. 28, 2017. The entire disclosures of all of the above applications are incorporated herein by reference.

### TECHNICAL FIELD

The present disclosure relates to a semiconductor device and a method for manufacturing the semiconductor device.

### BACKGROUND

A semiconductor device includes: a primary molded body having a semiconductor chip that has a detector for detecting physical quantities; a secondary molded resin that covers a primary molded body portion other than the detector; and a housing component that is attached to the secondary molded resin. In such a configuration, the primary molded body includes the semiconductor chip and a primary molded resin that covers a semiconductor chip region other than the detector.

### SUMMARY

The present disclosure describes a semiconductor device including a secondary molded body and a method for manufacturing the semiconductor device.

### BRIEF DESCRIPTION OF DRAWINGS

The above and other objects, features and advantages of the present disclosure will become more apparent from the following detailed description made with reference to the accompanying drawings. In the drawings:

FIG. 1 is a cross-sectional view of a semiconductor device according to the first embodiment;

FIG. 2 is a cross-sectional view of a clearance between a primary molded body and a housing component in a II-II cross section shown in FIG. 1;

FIG. 3A illustrates preparing of the primary molded body in manufacturing of the semiconductor device according to the first embodiment;

FIG. 3B illustrates attaching of the primary molded body onto the housing component, as a manufacturing step carried out subsequent to that of FIG. 3A;

FIG. 3C illustrates forming of a secondary molded resin, as a manufacturing step carried out subsequent to that of FIG. 3B;

FIG. 4 illustrates a situation in which a positional shift of the primary molded body is suppressed with use of the housing component by adjusting the difference in linear expansion coefficient between the primary molded body and the housing component and adjusting the clearance between the primary molded body and the housing component in an engagement of the primary molded body and the housing component in manufacturing of the semiconductor device according to the first embodiment;

FIG. 5 is a cross-sectional view illustrating a semiconductor device of the second embodiment;

FIG. 6A illustrates a receiving portion of the housing component formed in a region R in FIG. 5, and is an enlarged cross-sectional view illustrating the primary molded body during the insertion;

FIG. 6B is an enlarged cross-sectional view illustrating a manner of contact between the primary molded body and the receiving portion of the housing component into which the primary molded body has been inserted;

FIG. 7 is a cross-sectional view illustrating a rib formed in an insertion hole of the housing component in a VII-VII cross section in FIG. 5;

FIG. 8 is a cross-sectional view illustrating a semiconductor device of the third embodiment;

FIG. 9 is a cross-sectional view illustrating a semiconductor device of the fourth embodiment;

FIG. 10 is a cross-sectional view illustrating a semiconductor device of the fifth embodiment;

FIG. 11 is a cross-sectional view illustrating a semiconductor device of the sixth embodiment;

FIG. 12A illustrates preparing of the primary molded body to which a protection cap has been attached among the steps of manufacturing the semiconductor device of the sixth embodiment;

FIG. 12B illustrates forming of a secondary molded resin as a manufacturing step carried out subsequent to that of FIG. 12A;

FIG. 12C illustrates a secondary molded body after the manufacturing step of FIG. 12B;

FIG. 13 is a cross-sectional view illustrating an example of other molding dies used in the steps of manufacturing the semiconductor device of the sixth embodiment; and

FIG. 14 is a cross-sectional view illustrating a part of a semiconductor device of another embodiment.

### DETAILED DESCRIPTION

The semiconductor device in the related art includes a primary molded body provided with a semiconductor chip that has a detector for detecting pressure and a primary molded resin formed of a thermosetting resin; a secondary molded resin that covers a primary molded body region other than the semiconductor chip; and a housing component having a flange shape. Further, the housing component has an accommodation space formed to have a dome shape for covering the semiconductor chip and a hollow portion connected to the space, and is bonded to the primary molded body and the secondary molded resin via a sealing material so that the semiconductor chip exposed from the secondary molded resin is covered by the portion where the accommodation space has been formed. In the housing component having a flange shape, the diameter of the portion where the accommodation space has been formed is set to be larger than the diameter of the portion where the hollow portion has been formed.

The semiconductor device in the related field includes a step of fixing a primary molded body to a lower die belonging to a molding die made of the upper die, the lower die, and the slide die, and thereafter allowing a thermoplastic resin material flow thereinto for curing by insert molding, thereby to mold a secondary molded resin that covers a part of the primary molded body. Through this step, a secondary molded body is obtained in which the semiconductor chip in the primary molded body is exposed from the secondary molded resin, and in which an annular groove used for filling with a sealing material for bonding to the housing component between the primary molded resin and the secondary molded resin is formed. Further, after this groove of the secondary molded body is filled with the sealing material, the secondary molded body and the aforementioned housing component are bonded via the sealing material, whereby it is possible to manufacture a semiconductor device such as described above.

However, in the semiconductor device provided with the secondary molded body, the three members, which are the primary molded resin, the secondary molded resin, and the housing component, are bonded by one sealing material. For this reason, when these three members are different from each other in linear expansion coefficient, there is a need to adjust the linear expansion coefficient of the sealing material in order to alleviate the stress caused by heat; however, the adjustment is difficult, thereby possibly lowering the reliability of the bonding of the semiconductor device.

In the above manufacturing step, the primary molded body is set in the lower die of the molding die, and the secondary molded resin is molded by insert molding, so that the load at the time of injecting a material of the secondary molded resin into the molding die is applied to the primary molded body, thereby raising an issue that warpage or cracks may be generated in the primary molded body. Specifically, in the above manufacturing step, the material of the secondary molded resin is injected after the primary molded body is set in the hard lower die, so that the load applied to the primary molded body by injection of the material has no way out. Since the contact area between the primary molded body and the lower die where the primary molded body is set is small, the action of fixing the primary molded body in injecting the material of the secondary molded resin is weak. When warpage or cracks are generated in the primary molded body due to these causes, the manufactured semiconductor device may have warpage or cracks in the primary molded body.

In one or more embodiments of the present disclosure, a semiconductor device is provided with suppressed warpage or cracks in a primary molded body while having a structure provided with a secondary molded body having the primary molded body and a secondary molded resin.

A semiconductor device according to a first aspect of the present disclosure includes: a primary molded body includes a semiconductor chip that has a detector for detecting a physical quantity, and a primary molded resin made of a resin material; a housing component includes an insertion hole for inserting the primary molded body; and a secondary molded resin, which is made of a resin material, that integrally covers a region exposed from the insertion hole, the region being a part of a surface of the primary molded body, and a part of a region of a surface of the housing component including a region surrounding the insertion hole. Additionally, a part of the primary molded body including the semiconductor chip is inserted into the insertion hole.

Accordingly, the semiconductor device has a structure in which, while the primary molded body is inserted into an insertion hole of a housing component, the secondary molded resin covers the primary molded body surface portion exposed from the insertion hole and the housing component surface portion surrounding the insertion hole. For this reason, the housing component is bonded to the secondary molded resin by a wide area, thereby providing a semiconductor device having a higher reliability of bonding as compared with an ordinary semiconductor device in which the housing component is bonded to the primary molded resin and the secondary molded resin via a sealing material in a boundary region between the primary molded resin and the secondary molded resin.

A method for manufacturing a semiconductor device according to a second aspect of the present disclosure includes: preparing a primary molded body having a semiconductor chip with a detector for detecting a physical quantity, and a primary molded resin formed of a resin material; preparing a housing component in which an insertion hole for inserting the primary molded body is formed; inserting the primary molded body into the insertion hole to fit the primary molded body into the housing component; and setting the housing component, into which the primary molded body has been fit, in a molding die and allowing a resin material flow into the molding die by insert molding, followed by cooling and curing to mold a secondary molded resin which integrally covers a region exposed from the insertion hole, said region being a part of a surface of the primary molded body, and a housing component surface region including a region surrounding the insertion hole.

Accordingly, the secondary molded resin is molded by insert molding after the primary molded body is inserted into the housing component. Therefore, the load applied to the primary molded body in injecting the secondary molded resin into a molding die is absorbed by the housing component and alleviated, whereby cracks in the primary molded body are suppressed. The material of the secondary molded resin is injected after the primary molded body is inserted into and engaged with the insertion hole of the housing component, so that the action of fixing the primary molded body is strong, and warpage caused by the load in injecting the material is suppressed. As a result, it is possible to manufacture a semiconductor device having a high bonding reliability in which warpage or cracks of the primary molded body are suppressed, and in which the secondary molded resin and the housing component are bonded by a wider area, as compared with an ordinary semiconductor device.

It is possible to manufacture a semiconductor device with a smaller amount of warpage or cracks in the primary molded body, as compared with an ordinary semiconductor device, even in a case in which the secondary molded resin cannot be subjected to insert molding while the primary molded body is set in the housing component. Specifically, even when the secondary molded resin is subjected to insert molding after a protection cap made of an elastic body is attached to the semiconductor chip in the primary molded body, the protection cap alleviates the load applied to the primary molded body, so that warpage or cracks are hardly generated in the primary molded body. A semiconductor device with a smaller amount of warpage or cracks in the primary molded body, as compared with an ordinary semiconductor device, can be manufactured by fitting a secondary structure, in which a part of the primary molded body molded in this manner is covered with the secondary molded resin, into the housing component after removing the protection cap from the secondary structure. Hereafter, the following describes embodiments of the present disclosure with reference to the attached drawings. Here, in each of the following embodiments, parts identical or equivalent to each other are denoted with the same reference numerals for description.

### First Embodiment

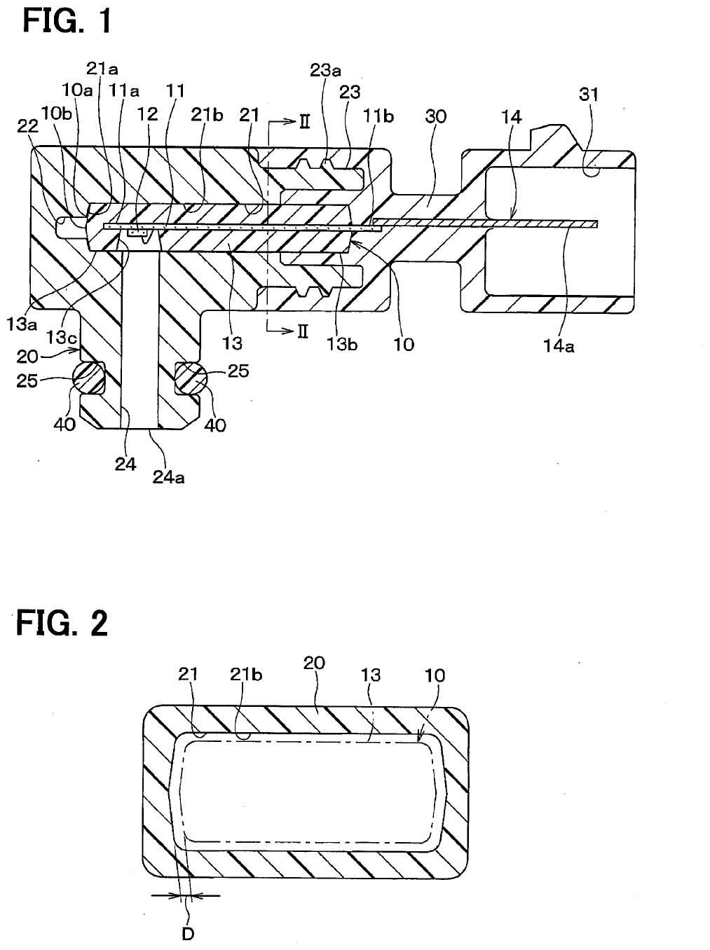

A semiconductor device according to the first embodiment is described with reference to FIGS. 1 to 4. In FIG. 2, the outline of a primary molded body 10 inserted in a later-mentioned insertion hole 21 is shown by a one-dot chain line.

In the present embodiment, description will be given by mentioning a semiconductor device made into a pressure sensor as an example. The pressure sensor of the present embodiment, which serves as an attachment member, may be attached on an engine of an automobile and used for detecting the pressure within a combustion chamber of the engine.

As illustrated in FIG. 1, the semiconductor device of the present embodiment includes: a primary molded body 10 having a semiconductor chip 12; a housing component 20 into which a part of the primary molded body 10 is inserted; and a secondary molded resin 30 that integrally covers a part of the primary molded body 10 and a part of the housing component 20.

As illustrated in FIG. 1, the primary molded body 10 includes: a circuit substrate 11; the semiconductor chip 12 mounted on the circuit substrate 11; a primary molded resin 13 that seals a part of the circuit substrate 11; and an electrical connection member 14 that is electrically connected to the circuit substrate 11. The circuit substrate 11 has: a first end 11a where the semiconductor chip 12 is mounted; and a second end 11b that is opposite to the first end 11a and is exposed from the primary molded resin 13 and electrically connected to the electrical connection member 14. In the present embodiment, the semiconductor chip 12 is exposed from the primary molded resin 13 in a normal line direction relative to one surface of the circuit substrate 11 on which the semiconductor chip 12 is mounted.

As illustrated in FIG. 1, in the present embodiment, the primary molded resin 13 has: a first end side 13a that covers a region of the first end 11a side of the circuit substrate 11; and a second end side 13b opposite to the first end side 11a. The first end side 13a of the primary molded body 10 is inserted in the insertion hole 21 formed in the later-described housing component 20. In the present embodiment, the second end side 13b of the primary molded body 10 protrudes from the insertion hole 21 of the housing component 20 to be exposed from the housing component 20. The rest of the second end side 13b of the primary molded body 10 exposed from the housing component 20 excluding an end portion 14a of the electrical connection member 14 is covered with the secondary molded resin 30. Further, the end portion 14a of the electrical connection member 14 protrudes from the secondary molded resin 30 to be exposed from the secondary molded resin 30.

The primary molded body 10 is formed, for example, by putting a circuit substrate 11, on which the semiconductor chip 12 is mounted and which is electrically connected to the electrical connection member 14, into a molding die (not shown) and molding the primary molded resin 13 and performing a thermosetting treatment. The molding may be, for example, transfer molding or compression molding.

When a later-mentioned step of molding the secondary molded resin 30 is regarded as the secondary molding, the “primary molding” refers to a step of molding the primary molded body 10 which is a step carried out prior to the secondary molding.

The circuit substrate 11 has one surface, and the semiconductor chip 12 is mounted on the one surface of the circuit substrate 11. The first end 11a side of the circuit substrate 11 on which the semiconductor chip 12 is mounted is sealed with the primary molded resin 13, and the second end 11b side opposite thereto is exposed from the primary molded resin 13.

The circuit substrate 11 may be formed with a circuit wiring made of an electroconductive material on the circuit substrate 11, or may be a lead frame having an island part and a lead part obtained by processing a metal plate made of metal.

The semiconductor chip 12 is made, for example, of a semiconductor material such as Si and is mounted on the circuit substrate 11 via an electroconductive adhesive or the like. For example, the semiconductor chip 12 includes a detector that is configured to generate an electric output in accordance with the physical quantities such as the pressure, magnetism, or light quantity of an ambient measurement medium and electrically connected to the circuit substrate 11 with a wire or the like, and is formed by a semiconductor process. In the present embodiment, the semiconductor chip 12 includes a detector that detects the pressure and is exposed from the primary molded resin 13 so as to be exposed to the measurement medium. Further, as illustrated in FIG. 1, the semiconductor chip 12 faces an inner space 24 of the housing component 20 and outputs an electric signal according to the pressure of the measurement medium introduced from an opening 24a connected to the inner space 24 of the housing component 20.

The primary molded resin 13 is made, for example, of a thermosetting resin such as an epoxy resin and covers a part of the circuit substrate 11, as shown in FIG. 1, and is formed with a recess 13c for exposing the semiconductor chip 12. The primary molded resin 13 is formed, for example, by performing molding such as transfer molding or compression molding and performing a thermosetting treatment.

In view of adjustment of the linear expansion coefficient or the like, a filler made of an insulating material such as silica or alumina may be included into the primary molded resin 13. When an additive is incorporated into the secondary molded resin 30, the additive and another additive having a functional group may be added in view of the improvement in the adhesion to the secondary molded resin 30.

The electrical connection member 14 is electrically connected to the second end 11b side of the circuit substrate 11 that is exposed from the primary molded resin 13 via an electroconductive adhesive (not shown) or the like. In the present embodiment, an example is shown in which a terminal is used as the electrical connection member 14; however, a circuit substrate on which a circuit wiring has been formed may be used as the electrical connection member 14.

The housing component 20 may suppress generation of warpage or cracks in the primary molded body 10 by absorbing the load applied to the primary molded body 10 during the insert molding of the secondary molded resin 30 while inserting, engaging, and fixing the primary molded body 10 in a manufacturing step.

The housing component 20 is, for example, an elastic body made of a resin material such as a thermosetting resin such as an epoxy resin or a thermoplastic resin such as PPS (polyphenylene sulfide), and is formed by performing molding such as transfer molding or injection molding, performing a heat treatment, or the like. The housing component 20 may be configured from a material having a larger linear expansion coefficient than the material of the primary molded resin 13 of the primary molded body 10 in view of suppressing positional shift during the insertion of the primary molded body 10 and absorbing the load applied to the primary molded body 10 as described above. The actions such as absorption of the load applied to the primary molded body 10 by the housing component 20 is described in the manufacturing step.

A filler made of an insulating material such as Si or the like may be added to the housing component 20 in view of adjustment of the linear expansion coefficient. When an additive having a functional group is added to the secondary molded resin 30, an additive having a functional group that reacts with the functional group may be added to the housing component 20 in view of improvement in the adhesion to the secondary molded resin 30.

As illustrated in FIG. 1, the housing component 20 has an insertion hole 21 formed therein so as to insert a primary molded body 10 portion including the semiconductor chip 12. Assuming that a primary molded body 10 surface in a direction along which the insertion hole 21 extends (hereafter referred to as “insertion direction”) is an insertion surface 10a, a bottom surface 21a of the insertion hole 21 when the insertion hole 21 is viewed in the insertion direction is in contact with a part of the insertion surface 10a.

Specifically, an insertion surface 10a part that is different from a tip end part 10b protruding in the insertion direction is in contact with the bottom surface 21a. In other words, in the present embodiment, the bottom surface 21a is formed as a pressing surface that receives a part of the insertion surface 10a of the primary molded body 10 inserted in the insertion hole 21. A recessed part 22 that is recessed along the insertion direction is formed in the bottom surface 21a. This is for suppressing application of the load to the tip end part 10b to prevent damage and the like of the primary molded body 10 that is caused by insert molding of the secondary molded resin 30 while the tip end part 10b is in contact with the bottom surface 21a in the manufacturing step. The details are described in the description of the manufacturing step.

As illustrated in FIG. 2, the gap D between the inner wall surface 21b of the insertion hole 21 and the primary molded body 10 when the insertion hole 21 is viewed in the insertion direction may be set to be 200 μm or less. This is because, when the gap D exceeds 200 μm, faults such as positional shift of the primary molded body 10 when the primary molded body 10 is inserted into the insertion hole 21 or during the insert molding of the secondary molded resin 30 or generation of resin burr caused by excessive invasion of a secondary molded resin material 30a into the gap may be generated.

As illustrated in FIG. 1, the housing component 20 has a housing sealing portion 23 formed to have a dimension in a radial direction with respect to the insertion direction serving as an axis (hereafter simply referred to as “radial direction”) that is smaller than the dimension of the other parts of the housing component 20 in the radial direction.

As viewed in the insertion direction, the housing sealing portion 23 is formed to have a substantially quadrangular frame shape and to surround the primary molded resin 13 of the primary molded body 10 at a distance. As illustrated in FIG. 1, the housing sealing portion 23 is a housing component 20 region including the region surrounding the insertion hole 21 and is covered by the secondary molded resin 30 together with a primary molded body 10 portion exposed from the insertion hole 21. In the present embodiment, the housing sealing portion 23 is covered by the secondary molded resin 30 to form a pressure sealing portion that is sealed so that the pressure applied to the semiconductor chip 12 does not leak to the outside from the insertion hole 21.

Herein, the housing component 20 may be configured by a material different from the material of the secondary molded resin 30 as long as the housing component 20 adheres to the secondary molded resin 30. However, the housing component 20 may also be configured by a material which is the same as the material of the secondary molded resin 30. This is because, when the surface of the housing sealing portion 23 becomes a region where the same materials are integrated and bonded to each other, the surface of the housing sealing portion 23 is brought into a state where no definite interface to the surface of the secondary molded resin 30 is generated. Thus, adhesion to the secondary molded resin 30 may be improved, and it is possible to suppress pressure leakage from the insertion hole 21.

As illustrated in FIG. 1, a protrusion 23a for enhancing the adhesion to the secondary molded resin 30 may be formed in an outer circumferential portion of the housing sealing portion 23, as viewed in the insertion direction. However, it may not be limited to the protrusion 23a. A roughened region or the like where a recess and a protrusion exhibiting an anchoring effect are formed may be provided.

The housing component 20 may be directly attached to a target of attachment (not shown) such as a combustion pipe, and has a groove 25 formed in the outer circumferential surface for attaching an O-ring 40 for sealing when the housing component 20 is attached to the target of attachment. Thus, by being attached to, for example, the combustion pipe, the opening 24a is brought into communication with the inside of the combustion pipe, whereby the measurement medium can be introduced into the inner space 24.

In the aforementioned example, attachment to the target of attachment located outside and sealing have been described; however, it is sufficient when a structure enabling attachment to the target of attachment located outside is formed in the housing component 20, and the O-ring 40 for sealing may be attached in accordance with the needs. For example, a screw that is engaged with the target of attachment located outside for attachment may be formed in the housing component 20, or another attachment structure may be formed in the housing component 20.

The secondary molded resin 30 is configured by, for example, a resin material such as a thermoplastic resin. The thermoplastic resin may be, for example, PPS or PBT (polybutylene terephthalate). Herein, a filler made of an insulating material or an additive may be added to the secondary molded resin 30 in the same manner as the primary molded resin 13 and the housing component 20.

The secondary molded resin 30 is a member that covers a portion of the surface of the primary molded body 10, which is exposed from the insertion hole 21 (hereafter referred to as “primary molded body exposed portion”), and the housing sealing portion 23 of the housing component 20. In other words, the secondary molded resin 30 adheres to the primary molded body exposed portion and the housing sealing portion 23, and forms a pressure sealing part at the interface between these two sites. The secondary molded resin 30 is formed, for example, by inserting the primary molded body 10 into the insertion hole 21 of the housing component 20, setting the resultant into a molding die, and thereafter performing an insert molding of allowing a molten thermoplastic resin material or the like flow thereinto, followed by cooling for curing.

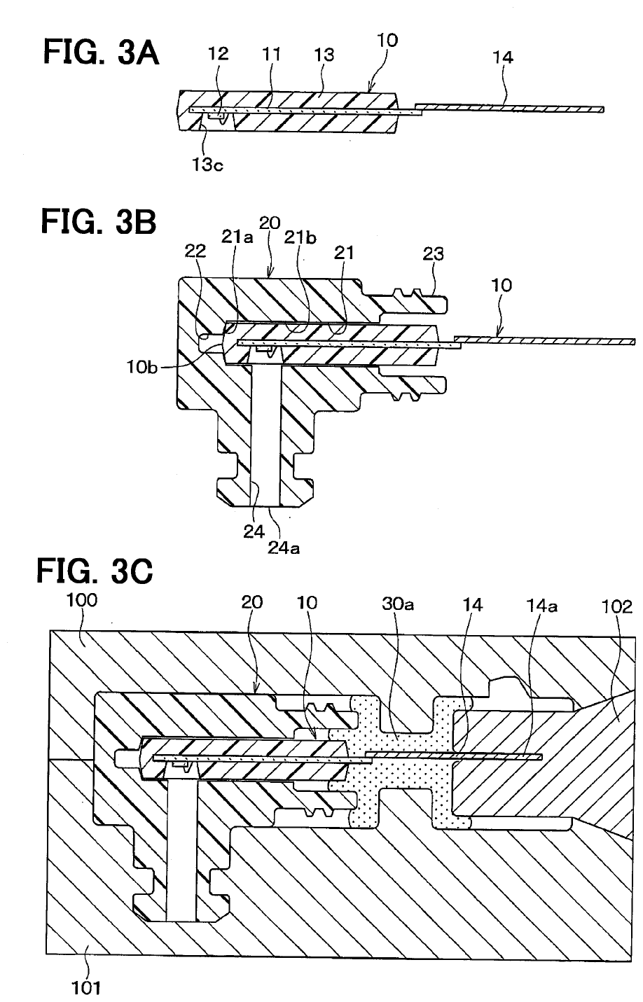

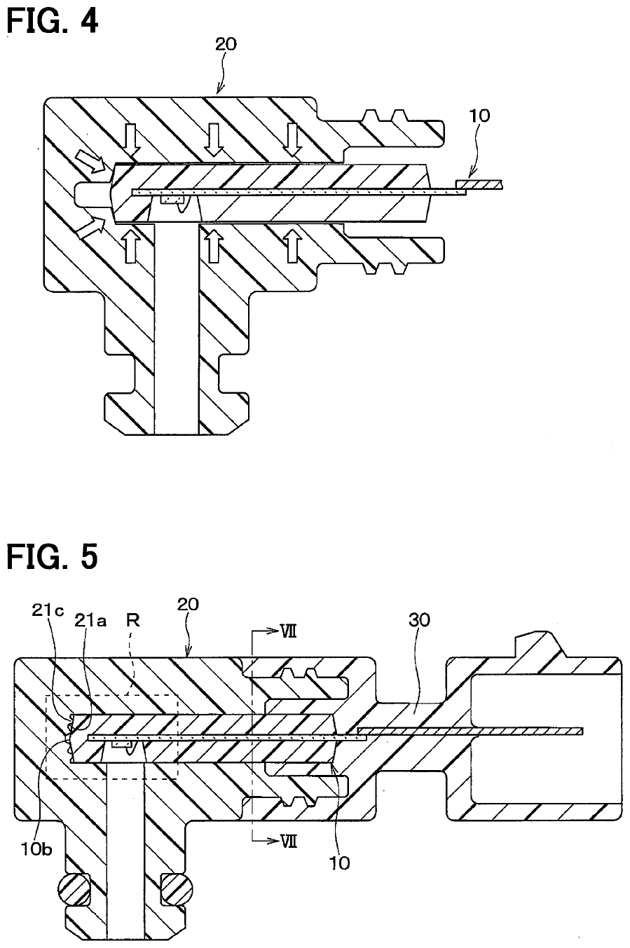

The above describes a basic configuration of the semiconductor device of the present embodiment. The following describes steps of manufacturing the semiconductor device of the present embodiment with reference to FIGS. 3 and 4. In FIG. 4, illustration of a part of the primary molded body 10, the secondary molded resin material 30a, and the molding die is omitted for easier understanding of the suppression of positional shift of the primary molded body 10 by the housing component 20 during the insert molding of the secondary molded resin 30.

First, a primary molded body 10 shown in FIG. 3A is prepared. The primary molded body 10 is obtained, for example, by molding a circuit substrate 11 through a primary molded resin 13 with use of a molding die (not shown), thereafter mounting a semiconductor chip 12 on a recess 13c of the circuit substrate 11, and connecting the resultant to an electrical connection member 14.

Subsequently, a housing component 20 in which an insertion hole 21 has been formed is prepared, and the primary molded body 10 is inserted into the insertion hole 21, as shown in FIG. 3B. At this time, the gap D between the inner wall surface 21b and the primary molded body 10 when the insertion hole 21 is viewed in the insertion direction is set to be 200 μm or less, as shown in FIG. 2. In this manner, it is possible to suppress positional shift of the primary molded body 10 by setting the gap D between the inner wall surface 21b and the primary molded body 10 to have a low clearance of 200 μm or less and fitting the primary molded body 10 into the insertion hole 21.

At this time, it is possible to adjust the linear expansion coefficients of the materials of the housing component 20 and the primary molded resin 13. Accordingly, the gap D is narrowed to allow the housing component 20 to press the primary molded body 10 by heating in the molding die in the following insert molding of the secondary molded resin 30. This is because, as shown in FIG. 4, the primary molded body 10 is pressed by thermal expansion of the housing component 20 to suppress positional shift of the primary molded body 10, when the housing component 20 and the primary molded body 10 are heated in the molding die at the time of the insert molding of the secondary molded resin 30 in the following step.

Specifically, for example, while the housing component 20 is configured by a material having a large linear expansion coefficient, the primary molded resin 13 of the primary molded body 10 is configured by a material having a smaller linear expansion coefficient than the material of the housing component 20 so that the gap D is narrowed by thermal expansion accompanying the heating. Therefore, a force in the direction of an arrow symbol shown in FIG. 4, that is, a force pressing the primary molded body 10, is generated by dimensional change of the housing component 20, when the housing component 20 and the primary molded body 10 are heated in the molding die. By using this force, the positional shift of the primary molded body 10 is suppressed.

As illustrated in FIG. 3B, when the primary molded body 10 is inserted into the insertion hole 21, the tip end part 10b of the insertion surface 10a of the primary molded body 10 may be on the recessed part 22 formed in the housing component 20 as viewed in the insertion direction. In other words, it may be preferable not to bring the tip end part 10b of the primary molded body 10 into contact with the bottom surface 21a of the housing component 20, and it may be preferable to bring a part of the insertion surface 10a of the primary molded body 10 different from the tip end part 10b into contact with the bottom surface 21a. This is for avoiding a situation in which the load applied to the primary molded body 10 is concentrated on the tip end part 10b at the time of the later-mentioned insert molding of the secondary molded resin 30, and for avoiding decrease in the reliability of the semiconductor device by generation of residual stress in the circuit substrate 11 as well as in the semiconductor chip 12 and the like mounted on the circuit substrate 11.

Specifically, in the primary molded body 10, the circuit substrate 11 is disposed on a straight line passing through the tip end part 10b in the insertion direction, so that, when an excessive load is applied onto the tip end part 10b by contact of the tip end part 10b with the bottom surface 21a of the housing component 20, the force thereof is transmitted to the circuit substrate 11 as well. Then, a force is applied to the circuit substrate 11 in a direction opposite to the insertion direction to generate a residual stress in the circuit substrate 11, and the semiconductor chip 12 and the like mounted on the circuit substrate 11 as well may be affected thereby. This may lead to a fault such as damage of the primary molded body 10 may be generated.

A recessed part 22 is provided in the bottom surface 21a of the housing component 20 so that the tip end part 10b may not be brought into contact with the bottom surface 21a of the housing component 20, and a part of the insertion surface 10a of the primary molded body 10 different from the tip end part 10b is brought into contact with the bottom surface 21a. Therefore, it may be possible to avoid generation of the fault.

As illustrated in FIG. 3C, for example, the primary molded body 10 is inserted into the housing component 20; the resultant is set in a molding die made of an upper die 100, a lower die 101, and a slide die 102; and a secondary molded resin material 30a made of a thermoplastic resin is injected into the molding die. This brings a state in which the secondary molded resin material 30a covers the primary molded body exposed portion in the primary molded body 10 excluding the end portion 14a of the electrical connection member 14 and a part of the housing component 20 surface region surrounding the insertion hole 21. The secondary molded resin material 30a is cured to obtain the secondary molded resin 30 that covers a part of the primary molded body 10 and a part of the housing component 20, whereby it is possible to manufacture the semiconductor device of the present embodiment shown in FIG. 1.

According to the semiconductor device of the present embodiment, a structure is provided in which the primary molded body exposed portion in the primary molded body 10 and the housing sealing portion 23 in the housing component 20 are covered by the secondary molded resin 30, while the primary molded body 10 is inserted into the insertion hole 21 of the housing component 20. For this reason, the housing component 20 is bonded to the secondary molded resin 30 by a wide area, thereby forming a semiconductor device having a higher reliability of bonding as compared with an ordinary semiconductor device. Furthermore, the structure in which the primary molded body 10 is inserted into the insertion hole 21 of the housing component 20 provides a semiconductor device in which warpage of the primary molded body 10 is suppressed more as compared with an ordinary semiconductor device.

According to the method of manufacturing the semiconductor device of the present embodiment, the secondary molded resin 30 is subjected to insert molding after the primary molded body 10 is inserted into the insertion hole 21 of the housing component 20, so that, at the time of injecting the secondary molded resin 30 into the molding die, the load applied to the primary molded body 10 goes along the insertion direction. Further, the housing component 20 configured by an elastic body such as a resin material receives the primary molded body 10 at the bottom surface 21a of the insertion hole 21, thereby to absorb the load applied to the primary molded body 10. For this reason, in the step of manufacturing the semiconductor device, it is possible to alleviate the load applied to the primary molded body 10 by the secondary molded resin material 30a and to suppress generation of cracks in the primary molded body 10.

The primary molded body 10 is inserted into the housing component 20, and the housing sealing portion 23 in the housing component 20 is bonded to the secondary molded resin 30, thereby attaining a larger bonding area as compared with an ordinary semiconductor device, and it is possible to manufacture a semiconductor device having a higher reliability of bonding.

The primary molded body 10 is inserted into the insertion hole 21 of the housing component 20, and the secondary molded resin 30 is subjected to insert molding, so that the primary molded body 10 is fixed not only on one surface but on the entire outer circumferential surface, and the load applied to the primary molded body 10 is limited only to the insertion direction. For this reason, it is possible to manufacture a semiconductor device in which warpage of the primary molded body 10 caused by the load of the insert molding is suppressed more as compared with an ordinary semiconductor device.

### Second Embodiment

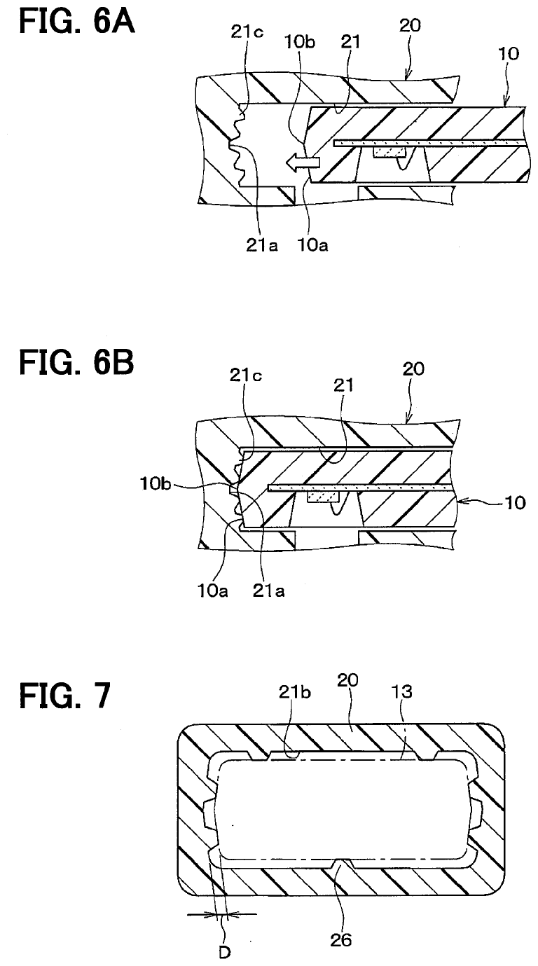

A semiconductor device according to the second embodiment will be described with reference to FIGS. 5 to 7. In FIG. 6, illustration of elements other than the region R shown in FIG. 5 is omitted for easier understanding of absorption of load into the primary molded body 10 in the insert molding of the secondary molded resin 30. In FIG. 7, the outline of the primary molded body 10 inserted into the insertion hole 21 is shown by a one-dot chain line.

As illustrated in FIG. 5 or 6, in the semiconductor device of the present embodiment, a receiving portion 21c for absorbing the load applied to the primary molded body 10 in the insert molding of the secondary molded resin 30 is formed, and the recessed part 22 is not formed in the bottom surface 21a of the insertion hole 21 of the housing component 20. As illustrated in FIG. 7, in the semiconductor device of the present embodiment, a rib 26 protruding towards the primary molded body 10 and serving to suppress positional shift of the primary molded body 10 is formed on the inner wall surface 21b of the insertion hole 21. In these points, the semiconductor device of the present embodiment is different from that of the first embodiment. These different points are mainly described in the present embodiment.

As illustrated in FIG. 5 or 6, the housing component 20 has a receiving portion 21c that protrudes from the bottom surface 21a of the insertion hole 21 in a direction opposite to the insertion direction and that serves to absorb the load applied to the primary molded body 10 in the insert molding of the secondary molded resin 30.

As illustrated in FIG. 6A, the receiving portion 21c is formed to have a shape protruding in the direction opposite to the insertion direction before the primary molded body 10 is inserted into the insertion hole 21. As illustrated in FIG. 6A, the receiving portion 21c absorbs the load applied to the primary molded body 10 by receiving the load and being deformed in the insert molding of the secondary molded resin 30 after the primary molded body 10 is inserted. At this time, the receiving portion 21c is disposed to be brought into contact with an insertion surface 10a portion different from the tip end part 10b in the primary molded body 10 so as to prevent the load from being applied to the tip end part 10b, in the same manner as the bottom surface 21a in the first embodiment.

The shape, the height, the number, and the like of the receiving portions 21c are arbitrary, so that the receiving portion 21c may be set to have a different shape or the like as long as the load is not applied to the tip end part 10b of the primary molded body 10. Thus, in the housing component 20, when the receiving portion 21c is formed on the bottom surface 21a, the recessed part 22 need not be formed in the bottom surface 21a.

As illustrated in FIG. 7, a rib 26 protruding in the radial direction and serving to suppress positional shift of the primary molded body 10 inserted into the insertion hole 21 is formed on the inner wall surface 21b of the housing component 20. Except for the part where the rib 26 is formed, the gap D between the inner wall surface 21b and the primary molded body 10 may be set to be 200 μm or less, as in the first embodiment. In other words, when such a gap D is provided, the rib 26 is set to have a height of 200 μm or less in the normal line direction relative to one surface of the inner wall surface 21b where the rib is formed.

In the present embodiment, when the housing component 20 is configured by an elastic body made of a resin material or the like, the housing component 20 may be easily drawn out from the molding die (not shown) even when the housing component 20 having the rib 26 formed therein is molded with use of the molding die. The shape of the rib 26, the number of the ribs 26 formed, the arrangement of the ribs 26, and the like are arbitrary. Thus, the rib 26 is not limited to an example shown in FIG. 7 in which the cross-sectional shape is set to be a trapezoidal shape. The cross-sectional shape may also be set to be a semicircular shape or a different shape, and the number of the ribs 26 formed, the arrangement of the ribs 26, and the like may be suitably changed.

According to the present embodiment, the structure is such that the housing component 20 is bonded to the secondary molded resin 30 by a wider area in a state in which the primary molded body 10 is inserted in the insertion hole 21 in the same manner as in the first embodiment described above. Therefore, a semiconductor device having a higher bonding reliability with less amount of warpage of the primary molded body 10 may be formed, as compared with an ordinary semiconductor device. The structure is such that the receiving portion 21c absorbs the load applied to the primary molded body 10, and the rib 26 suppresses positional shift of the primary molded body 10. Therefore, it is possible to form a semiconductor device in which faults such as cracks of the primary molded body 10 are furthermore suppressed, as compared with an ordinary semiconductor device.

By using the housing component 20 provided with the receiving portion 21c and the rib 26, it is possible to stably manufacture a semiconductor device in which faults such as cracks of the primary molded body 10 are furthermore suppressed while suppressing positional shift of the primary molded body 10, as compared with an ordinary semiconductor device.

### Third Embodiment

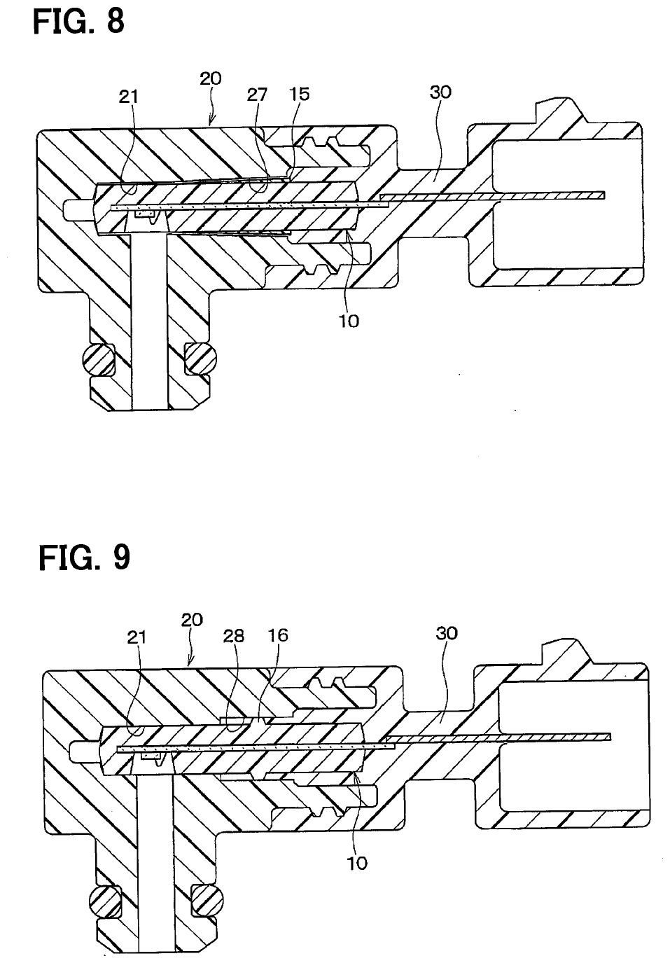

A semiconductor device according to the third embodiment is with reference to FIG. 8. As illustrated in FIG. 8, the semiconductor device of the present embodiment includes an inclined surface 27 which is disposed on the inner wall surface 21b of the housing component 20 and whose dimension in the radial direction increases according as it goes in the direction opposite to the insertion direction. An inclination-following protrusion 15 having a larger dimension in the radial direction along the inclination is formed on the primary molded resin 13 of the primary molded body 10. In these points, the semiconductor device of the present embodiment is different from that of the first embodiment. These different points are described in the present embodiment.

The housing component 20 is formed, for example, by injection molding or the like using a molding die (not shown). However, in order that the housing component 20 is easily taken out from the molding die after being formed, an inclined surface 27 whose dimension in the radial direction increases according as it goes in the direction opposite to the insertion direction is provided in the insertion hole 21.

When such a housing component 20 provided with an inclined surface 27 that facilitates take-out from the molding die is used, an inclination-following protrusion 15 having a larger dimension in the radial direction along the inclined surface 27 is formed on the primary molded body 10, as shown in FIG. 8. By this, the gap between the inner wall surface 21b and the primary molded body 10 as viewed in the insertion direction is prevented from becoming excessively large. It may be possible to suppress positional shift of the primary molded body 10 during the insertion of the primary molded body 10 or during the insert molding of the secondary molded resin 30.

It is possible that the inclination-following protrusion 15 has a shape that goes along the inclined surface 27. Therefore, the inclination-following protrusion 15 may be formed on a part of the outer circumference of the primary molded resin 13 or may be formed on the entire region of the outer circumference. The inclined surface 27 may have a constant inclination, or may have a gradually increasing inclination, or may have a stepwise increasing inclination, as it goes in a direction opposite to the insertion direction (in other words, a protrusion direction). The inclination of the inclined surface 27 is arbitrary.

According to the present embodiment, even when a housing component 20 in which the inclined surface 27 is formed in the insertion hole 21 is used, it is possible to form a semiconductor device having a higher reliability of bonding with a smaller amount of faults such as warpage or cracks of the primary molded body 10, as compared with an ordinary semiconductor device, in the same manner as in the first embodiment described above.

By using the housing component 20 provided with an insertion hole 21 formed to have a shape that facilitates drawing-out from the molding die, it is possible to stably manufacture a semiconductor device having a higher reliability of bonding with a smaller amount of faults such as warpage or cracks of the primary molded body 10.

### Fourth Embodiment

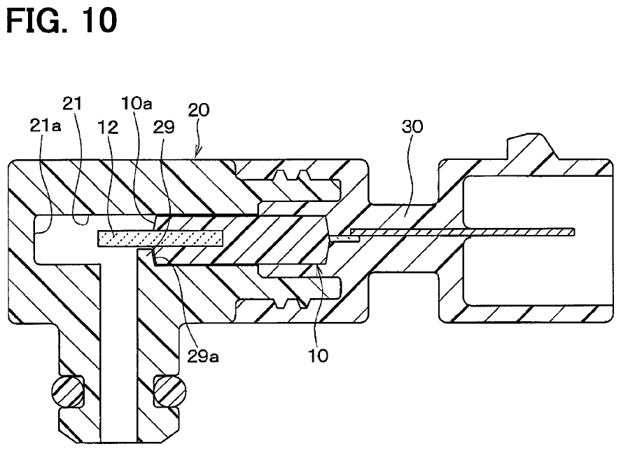

A semiconductor device according to the fourth embodiment is described with reference to FIG. 9. As illustrated in FIG. 9, the semiconductor device of the present embodiment is different from that of the first embodiment in that a burr-suppressing protrusion 16 is formed on the primary molded body 10, and a large-diameter portion 28 having a larger dimension in the radial direction of the insertion hole 21 is formed in the housing component 20 in correspondence with the burr-suppressing protrusion 16. This different point is mainly described in the present embodiment.

The burr-suppressing protrusion 16 is formed on the outer circumferential part of the primary molded resin 13 in the primary molded body 10, and is formed to have a shape that protrudes in the radial direction from the outer circumference and is formed, for example, to be an annular protrusion having a trapezoidal cross-sectional shape, as shown in FIG. 9. The burr-suppressing protrusion 16 is formed on the primary molded body 10 so as to suppress generation of resin burr caused by invasion of the secondary molded resin material 30a between the inner wall surface 21b of the insertion hole 21 and the primary molded body 10 at the time of insert molding of the secondary molded resin 30.

Specifically, flow of the secondary molded resin material 30a to the insertion hole 21 side is held back by the burr-suppressing protrusion 16 at the time of insert molding of the secondary molded resin 30. A portion of the secondary molded resin material 30a that goes over the burr-suppressing protrusion 16 stays in a space located in the gap between the large-diameter portion 28 and the primary molded body 10 and located beyond the burr-suppressing protrusion 16. For this reason, it is possible to suppress excessive invasion of the secondary molded resin material 30a between the primary molded body 10 and the inner wall surface 21b set to have a smaller dimension in the radial direction than the large-diameter portion 28 in the insertion hole 21. It is possible to suppress generation of resin burr between these.

As illustrated in FIG. 9, in the present embodiment, the large-diameter portion 28 having a larger dimension in the radial direction than the dimension of the insertion hole 21 in the radial direction (hereafter referred to as “insertion hole dimension”) is formed in the housing component 20 on the side opposite to the insertion direction in the insertion hole 21 into which the primary molded body 10 is inserted. The dimension of the large-diameter portion 28 in the radial direction (hereafter referred to as “large-diameter portion dimension”) is adjusted in accordance with the height dimension of the burr-suppressing protrusion 16, that is, the dimension of a portion of the outer circumference of the primary molded resin 13 in the normal line direction relative to one surface of the outer circumference of the primary molded resin 13 on which the burr-suppressing protrusion 16 is formed. Specifically, it may be sufficient that the large-diameter portion dimension is equal to or larger than the dimension obtained by adding the height dimension of the burr-suppressing protrusion 16 to the insertion hole dimension.

It is possible that the burr-suppressing protrusion 16 has a shape capable of receiving a part or whole of the secondary molded resin material 30a. Therefore, the burr-suppressing protrusion 16 may not be only limited to an example shown in FIG. 9 in which the cross-sectional shape is set to be a trapezoidal shape, and the cross-sectional shape may be set to have a semicircular shape or any other shape. The burr-suppressing protrusion 16 may be formed intermittently on a part of the outer circumference of the primary molded body 10 or may be formed continuously on the whole of the outer circumference. The height dimension of the burr-suppressing protrusion 16 and the large-diameter portion dimension are set to have any numerical values.

According to the present embodiment, generation of resin burr and faults caused by the generation of resin burr are suppressed by the burr-suppressing protrusion 16 and, in the same manner as in the first embodiment described above, it is possible to form a semiconductor device having a higher reliability of bonding with a smaller amount of faults such as warpage or cracks of the primary molded body 10, as compared with an ordinary semiconductor device.

### Fifth Embodiment

A semiconductor device according to the fifth embodiment is described with reference to FIG. 10. As illustrated in FIG. 10, in the semiconductor device of the present embodiment, a part of the region of the semiconductor chip 12 including the detector (not shown) is exposed from the insertion surface 10a along the insertion direction. The semiconductor device of the present embodiment has a structure such that a protrusion 29 protruding from the inner wall surface 21b of the insertion hole 21 in a direction intersecting the insertion direction is formed, and the protrusion 29 is in contact with the insertion surface 10a. In these points, the semiconductor device of the present embodiment is different from that of the first embodiment. These different points are mainly described in the present embodiment.

As illustrated in FIG. 10, in the present embodiment, the protrusion 29 is formed in the housing component 20 so that the primary molded body 10 set to have a structure such that a part of the region of the semiconductor chip 12 including the detector is exposed from the insertion surface 10a is not brought into contact with the bottom surface 21a of the insertion hole 21. Specifically, in the housing component 20, the protrusion 29 is formed on the inner wall surface 21b of the insertion hole 21 to protrude in a direction intersecting the insertion direction.

On the protrusion 29, a pressing surface 29a is formed to be brought into contact with a portion of the insertion surface 10a of the primary molded body 10 that is different from the tip end part 10b. In the protrusion 29, the dimension of the inner wall surface 21b in the normal line direction relative to one surface on which the protrusion 29 is formed is set to have a degree such that the protrusion 29 is not brought into contact with the semiconductor chip 12. In other words, the protrusion 29 is configured to receive the primary molded body 10 to absorb the load applied to the primary molded body 10 at the time of insertion of the primary molded body 10 into the insertion hole 21 and at the time of insert molding of the secondary molded resin 30 while preventing damage of the semiconductor chip 12 caused by contact with the housing component 20.

It is possible that the protrusion 29 is not brought into contact with the semiconductor chip 12 and receives the primary molded body 10 by being brought into contact with the insertion surface 10a. Therefore, the protrusion 29 may not be only limited to the example shown in FIG. 10 and may be formed, for example, so as to surround the semiconductor chip 12 from four sides or may be formed in a different arrangement.

According to the present embodiment, even when the primary molded body 10 has a structure such that a part of the semiconductor chip 12 is exposed from the insertion surface 10a, a semiconductor device having a higher reliability of bonding with a smaller amount of faults such as warpage or cracks of the primary molded body 10 may be formed, as compared with an ordinary semiconductor device, in the same manner as in the first embodiment described above.

Further, even when a primary molded body 10 in which the semiconductor chip 12 is exposed from the insertion surface 10a is used, it is possible to form a semiconductor device having a higher reliability of bonding with a smaller amount of faults such as warpage or cracks of the primary molded body 10 while preventing damage of the semiconductor chip 12.

### Sixth Embodiment

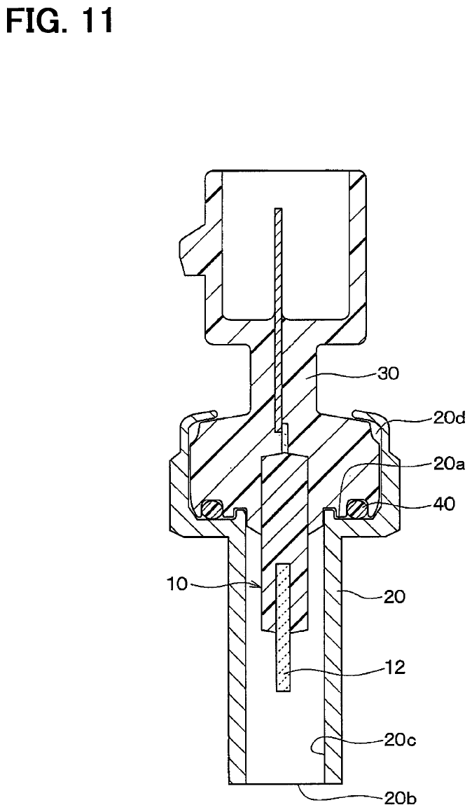

A semiconductor device according to the sixth embodiment is described with reference to FIGS. 11 to 13. The semiconductor device of the present embodiment is, as shown in FIG. 11, different from that of the fifth embodiment in that the semiconductor device has a structure in which a constituent element obtained by integration of the primary molded body 10 and the secondary molded resin 30 is connected to the housing component 20 made of a metal material. This different point is mainly described in the present embodiment.

In the present embodiment, the housing component 20 is provided, for example, with a hollow portion 20c and an accommodation region 20d into which a part of the primary molded body 10 is inserted, and is formed to have a flange shape such that the diameter of the part where the accommodation region 20d is formed is larger than the diameter of the part where the hollow portion 20c is formed. As illustrated in FIG. 11, unlike each of the above-described embodiments, the housing component 20 is connected by crimping to the constituent element (hereafter referred to as “secondary molded body” in the present embodiment) obtained by integration of the primary molded body 10 and the secondary molded resin 30 so as to cover a part of the secondary molded resin 30.

Specifically, referring to FIG. 11, the housing component 20 is sealed to the secondary molded body via an O-ring 40, for example, at one surface 20a corresponding to the bottom surface of the accommodation region 20d. A primary molded body 10 portion which includes the detector of the semiconductor chip 12 and which is exposed from the secondary molded resin 30 is accommodated in the hollow portion 20c. The detector of the semiconductor chip 12 outputs an electric signal corresponding to the pressure of a measurement medium that is introduced from an opening 20b formed in the housing component 20 and connected to the hollow portion 20c.

The housing component 20 may be configured from a resin material similar to that of each of the above-described embodiments or may be configured from a metal material.

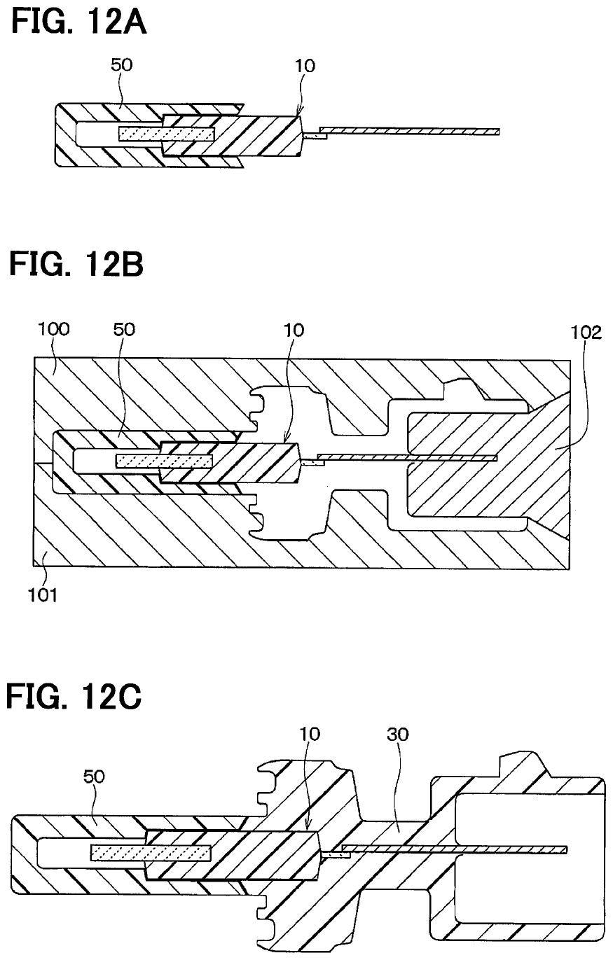

A method for manufacturing the semiconductor device of the present embodiment will be described with reference to FIGS. 12 and 13.

The primary molded body 10 in which a semiconductor chip 12 portion including the detector is exposed from the primary molded resin 13 is molded, for example, by transfer molding or the like with use of a molding die (not shown) or the like in the same manner as in each of the above-described embodiments.

A protection cap 50 made of an elastic body such as a thermoplastic resin material such as PPS is attached to cover the exposed portion of the semiconductor chip 12 in the primary molded body 10, as shown in FIG. 12A.

As illustrated in FIG. 12B, the primary molded body 10 having the protection cap 50 attached thereon is set in a molding die made of an upper die 100, a lower die 101, and a slide die 102. A secondary molded resin material 30a is injected into the molding die and cured, so as to obtain a secondary molded body to which the protection cap shown in FIG. 12C is attached.

Subsequently, the protection cap 50 is removed from the secondary molded body shown in FIG. 12C and, after an O-ring 40 is attached, the secondary molded body is sealed by crimping to the housing component 20, thereby to manufacture the semiconductor device of the present embodiment shown in FIG. 11.

As illustrated in FIG. 13, a die obtained by inserting a protection cap 50 into a slide die 103 different from the slide die 102 shown in FIG. 12B may be used, and the molding die put to use may be any suitable one. In the case in which the slide die 103 into which the protection cap 50 has been inserted is used, the protection cap 50 can be repeatedly used when the secondary molded body is drawn out from the slide die 103 after removing the upper die 100, the lower die 101, and the slide die 102 after the secondary molded resin 30 is formed.

According to the present embodiment, even with a structure in which insert molding of the secondary molded resin 30 cannot be carried out while the housing component 20 receives the primary molded body 10, a semiconductor device with suppressed warpage or cracks of the primary molded body 10 may be formed, as compared with an ordinary semiconductor device.

Even when the primary molded body 10 is used having a structure such that the load applied to the primary molded body 10 cannot be absorbed by the housing component 20 in performing insert molding of the secondary molded resin 30, damage of the semiconductor chip 12 may be prevented by using the protection cap 50. Further, by connecting the secondary molded body, from which the protection cap 50 has been removed, to the housing component 20, a semiconductor device with suppressed warpage or cracks of the primary molded body 10 can be manufactured, as compared with an ordinary semiconductor device.

### Other Embodiments

The present disclosure has been described in accordance with the embodiments; however, it is understood that the present disclosure may not be limited to the embodiments or structures. The present disclosure encompasses various modified examples and modifications within the range of equivalence. In addition, various combinations and modes, and further, other combinations and modes including one element of these alone, or thereabove, or therebelow, are also comprised within the scope or concept range of the present disclosure.

For example, in the semiconductor device of each of the aforementioned embodiments, an example has been described in which the primary molded resin 13 is configured by a thermosetting resin; however, the primary molded resin 13 may be configured by a thermoplastic resin such as PPS. At this time, when the semiconductor chip 12 is connected to the circuit substrate 11 by a wire, attention is paid so that the wire may not be disconnected by the thermoplastic resin.

In each of the aforementioned embodiments, an example has been described in which an element that detects pressure is used as the semiconductor chip 12 so that the semiconductor device as a whole is formed as a pressure sensor; however, the present disclosure is not limited to this alone, so that an element that detects other physical quantities such as magnetism or light quantity may be used as the semiconductor chip 12. In this case, the semiconductor chip 12 may be sealed with the primary molded resin 13, and a housing component 20 portion provided with the inner space 24 may be suitably changed in shape and the like in accordance with the shape and the like of the optional magnetism sensor or light quantity sensor.

In each of the embodiments from the first embodiment to the fifth embodiment, a semiconductor device having a structure obtained by combination of these may be manufactured. For example, in the semiconductor device of the first embodiment or in the semiconductor device of the fifth embodiment, the rib 26 or the receiving portion 21c formed in the semiconductor device of the second embodiment may be formed, or a semiconductor device having a structure obtained by combination of other embodiments with each other may be manufactured.

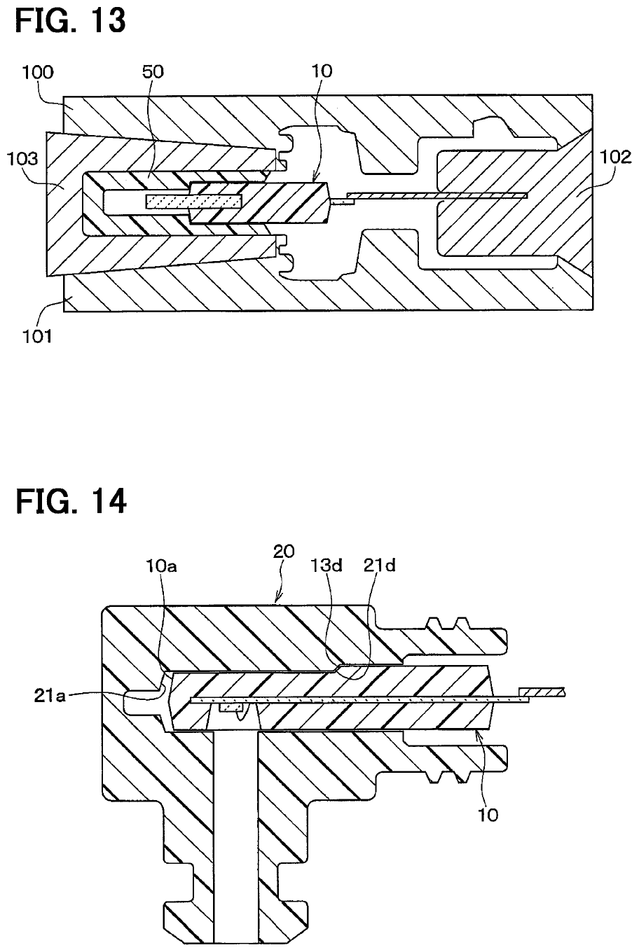

In the first embodiment to the fifth embodiment, an example has been described in which the surface which is either the bottom surface or the inner wall surface of the insertion hole 21 and which is in contact with the insertion surface 10a of the primary molded body 10 is set to be the pressing surface. However, as illustrated in FIG. 14, when the primary molded resin 13 of the primary molded body 10 has a shape provided with a part that protrudes in the radial direction, a structure may be formed in which a pressing surface 21d that receives a side surface 13d at the step difference of the protruding part in the primary molded resin 13 is formed in the insertion hole 21. In this case, as illustrated in FIG. 14, even if the insertion surface 10a is not in contact with the bottom surface 21a of the insertion hole 21, the pressing surface 21d is brought into contact with the side surface 13d to receive the primary molded body 10, thereby absorbing the load applied to the primary molded body 10. A semiconductor device may be manufactured having a structure in which the insertion surface 10a is in contact with the bottom surface 21a, and the pressing surface 21d is in contact with the side surface 13d.

In the first embodiment to the fifth embodiment, an example has been described in which the housing component 20 is an elastic body configured by a resin material. However, it is possible that the housing component 20 absorbs the load applied to the primary molded body 10 at the time of insert molding of the secondary molded resin 30, so that the housing component 20 may be configured by a relatively soft metal material such as Al. For example, by forming a structure in which the receiving portion 21c is formed to be fine protrusions while configuring the housing component 20 by Al, it is possible to absorb the load applied to the primary molded body 10 at the time of insert molding of the secondary molded resin 30, thereby forming a semiconductor device in which cracks and the like of the primary molded body 10 are suppressed.

What is claimed is:

1. A semiconductor device comprising:
a primary molded body including a semiconductor chip that has a detector for detecting a physical quantity, and a primary molded resin having a resin material;
a housing component including an insertion hole to which the primary molded body is inserted; and
a secondary molded resin that has a resin material, and that integrally covers
a region exposed from the insertion hole, the region being a part of a surface of the primary molded body, and
a part of a region of a surface of the housing component including a region surrounding the insertion hole,
wherein a part of the primary molded body including the semiconductor chip is in the insertion hole,
wherein a direction along which the insertion hole extends is an insertion direction,
wherein the primary molded body includes a burr-suppressing protrusion protruding along a radial direction with respect to the insertion direction serving as an axis, and
wherein the burr-suppressing protrusion is in the insertion hole.

2. The semiconductor device according to claim 1,
wherein a part of a surface of the primary molded body in the insertion direction is an insertion surface,
wherein the insertion hole has a pressing surface inside,
wherein the insertion surface has a tip end part, which protrudes along the insertion direction, and a part other than the tip end part,
wherein the pressing surface is in contact with the part other than the tip end part, the pressing surface receiving the primary molded body.

3. The semiconductor device according to claim 2,
wherein the pressing surface is a bottom surface of the insertion hole when the insertion hole is viewed in the insertion direction.

4. The semiconductor device according to claim 2,
wherein the pressing surface is a surface of a part of a protrusion at the insertion surface,
wherein the insertion hole includes an inner wall surface having a protrusion when the insertion hole is viewed in the insertion direction, and
wherein the protrusion protrudes from the inner wall surface in a direction intersecting the insertion direction.

5. The semiconductor device according to claim 3,
wherein the housing component includes a recessed part which is arranged in a region of the bottom surface overlapping with the tip end part as viewed in the insertion direction, and
wherein the recessed part is recessed from the bottom surface in the insertion direction.

6. A semiconductor device comprising:
a primary molded body including a semiconductor chip that has a detector for detecting a physical quantity, and a primary molded resin having a resin material;
a housing component including an insertion hole to which the primary molded body is inserted; and
a secondary molded resin that has a resin material, and that integrally covers
a region exposed from the insertion hole, the region being a part of a surface of the primary molded body, and
a part of a region of a surface of the housing component including a region surrounding the insertion hole,
wherein a part of the primary molded body including the semiconductor chip is in the insertion hole,
wherein a direction along which the insertion hole extends is an insertion direction,
wherein a part of a surface of the primary molded body in the insertion direction is an insertion surface,
wherein the insertion hole has a pressing surface inside,
wherein the insertion surface has a tip end part, which protrudes along the insertion direction, and a part other than the tip end part,
wherein the pressing surface is in contact with the part other than the tip end part, the pressing surface receiving the primary molded body,
wherein the pressing surface is a surface of a part of a protrusion at the insertion surface,
wherein the insertion hole includes an inner wall surface having a protrusion when the insertion hole is viewed in the insertion direction, and
wherein the protrusion protrudes from the inner wall surface in a direction intersecting the insertion direction.

7. A semiconductor device comprising:
a primary molded body including a semiconductor chip that has a detector for detecting a physical quantity, and a primary molded resin having a resin material;
a housing component including an insertion hole to which the primary molded body is inserted; and
a secondary molded resin that has a resin material, and that integrally covers
a region exposed from the insertion hole, the region being a part of a surface of the primary molded body, and
a part of a region of a surface of the housing component including a region surrounding the insertion hole,
wherein a part of the primary molded body including the semiconductor chip is in the insertion hole,
wherein a direction along which the insertion hole extends is an insertion direction,
wherein a part of a surface of the primary molded body in the insertion direction is an insertion surface,
wherein the insertion hole has a pressing surface inside,
wherein the insertion surface has a tip end part, which protrudes along the insertion direction, and a part other than the tip end part,
wherein the pressing surface is in contact with the part other than the tip end part, the pressing surface receiving the primary molded body,
wherein the pressing surface is a bottom surface of the insertion hole when the insertion hole is viewed in the insertion direction,
wherein the housing component includes a recessed part which is arranged in a region of the bottom surface overlapping with the tip end part as viewed in the insertion direction, and
wherein the recessed part is recessed from the bottom surface in the insertion direction.

8. The semiconductor device according to claim 2,
wherein the pressing surface includes a receiving portion, and
wherein the receiving portion protrudes towards the primary molded body and is in contact with the part of the insertion surface other than the tip end part, to receive the primary molded body.

9. A semiconductor device comprising:
a primary molded body including a semiconductor chip that has a detector for detecting a physical quantity, and a primary molded resin having a resin material;
a housing component including an insertion hole to which the primary molded body is inserted; and
a secondary molded resin that has a resin material, and that integrally covers
a region exposed from the insertion hole, the region being a part of a surface of the primary molded body, and
a part of a region of a surface of the housing component including a region surrounding the insertion hole,
wherein a part of the primary molded body including the semiconductor chip is in the insertion hole,
wherein a direction along which the insertion hole extends is an insertion direction,
wherein a part of a surface of the primary molded body in the insertion direction is an insertion surface,
wherein the insertion hole has a pressing surface inside,
wherein the insertion surface has a tip end part, which protrudes along the insertion direction, and a part other than the tip end part,
wherein the pressing surface is in contact with the part other than the tip end part, the pressing surface receiving the primary molded body,
wherein the pressing surface includes a receiving portion, and
wherein the receiving portion protrudes towards the primary molded body and is in contact with the part of the insertion surface other than the tip end part, to receive the primary molded body.

10. The semiconductor device according to claim 1,
wherein the insertion hole includes an inner wall surface having an inclined surface,
wherein the inclined surface has a dimension in a radial direction with respect to the insertion direction serving as an axis increases towards a protrusion direction when the insertion hole is viewed in the insertion direction, and
wherein the primary molded body includes an inclination-following protrusion, whose dimension in the radial direction increases along an inclination.

11. A semiconductor device comprising:
a primary molded body including a semiconductor chip that has a detector for detecting a physical quantity, and a primary molded resin having a resin material;
a housing component including an insertion hole to which the primary molded body is inserted; and
a secondary molded resin that has a resin material, and that integrally covers
a region exposed from the insertion hole, the region being a part of a surface of the primary molded body, and
a part of a region of a surface of the housing component including a region surrounding the insertion hole,
wherein a part of the primary molded body including the semiconductor chip is in the insertion hole,
wherein a direction along which the insertion hole extends is an insertion direction,
wherein the insertion hole includes an inner wall surface having an inclined surface,
wherein the inclined surface has a dimension in a radial direction with respect to the insertion direction serving as an axis increases towards a protrusion direction when the insertion hole is viewed in the insertion direction, and
wherein the primary molded body includes an inclination-following protrusion whose dimension in the radial direction increases along an inclination.

12. The semiconductor device according to claim 1,
wherein a direction along which the insertion hole extends is an insertion direction, and
wherein a gap between the primary molded body and an inner wall surface of the insertion hole when the insertion hole is viewed in the insertion direction is 200 μm or less.

13. The semiconductor device according to claim 1,
wherein a direction along which the insertion hole extends is an insertion direction,
wherein the housing component includes a rib, which protrudes along a radial direction with respect to the insertion direction serving as an axis, at an inner wall surface of the insertion hole as viewed in the insertion direction.

14. The semiconductor device according to claim 1,
wherein the housing component is an elastic body having a resin material.

15. The semiconductor device according to claim 14,
wherein the housing component is made of an identical resin material as the secondary molded resin.

16. A method for manufacturing a semiconductor device, comprising:
preparing a primary molded body including a semiconductor chip having a detector for detecting a physical quantity, and a primary molded resin having a resin material to seal a region of the semiconductor chip other than the detector;
attaching a protection cap having an elastic body to the semiconductor chip exposed from the primary molded resin in the primary molded body;
setting the primary molded body attached with the protection cap in a molding die, and allowing a resin material flow into the molding die by insert molding, followed by cooling and curing to form a secondary molded resin which covers a part of the primary molded body part at a side opposite to a part of the primary molded body where the protection cap has been attached;
preparing a housing component in which an insertion hole is formed for inserting a part of the primary molded body exposed from the secondary molded body; and
removing the protection cap from the primary molded body which is partially sealed with the secondary molded resin, and fitting the primary molded body into the housing component.
